(19) United States
(12) Patent Application Publication
(10) Pub. No.: US 2026/0181808 A1
(43) Pub. Date: Jun. 25, 2026

(54) POWER INPUT CONNECTOR MODULE FOR AN INFORMATION PROCESSING DEVICE

(71) Applicant: Hewlett Packard Enterprise Development LP, Spring, TX (US)

(72) Inventors: Chih-Wei Chiang, Taipei (TW); Chui Ching Chiu, Taipei (TW); Chiung-Chao Hsieh, Taipei (TW)

(21) Appl. No.: 18/989,606

(22) Filed: Dec. 20, 2024

(51) Int. Cl. H05K 7/14; H01R 13/518

(52) U.S. Cl. CPC H05K 7/1457; H01R 13/518

(57) ABSTRACT

includes a movable member, a first power input connector, and a second power input connector. The movable member is configured to be movably connected to a chassis of the information processing device such that the movable member is movable outside the chassis to an extended position and inside the chassis to a retracted position. The first and second power input connectors are disposed serially spaced apart from each other along an axis parallel to a direction of movement of the movable member and coupled to the chassis via the movable member. The movable member supports the first and second power input connectors relative to the chassis. The first and second power input connectors are configured to travel along with the movable member relative to the chassis as the movable member moves between the extended position and the retracted position.

### BACKGROUND

Information processing devices may include a power supply unit (PSU) which is configured to receive power, regulate the received power, and supply the regulated power to a plurality of electronics components of the information processing device. In one or more cases, the PSU may include a power input connector which is configured to detachably mate with a power source connector of an external power cord to receive the power from an external power source unit. Further, the power input connector is generally disposed in a housing of the PSU at a position which will be physically accessible from outside of a chassis of the information processing device when the PSU is installed therein such that the power input connector is physically accessible to detachably mate with the power source connector.

### BRIEF DESCRIPTION OF THE DRAWINGS

Various examples will be described below with reference to the following figures.

FIG. 1A includes a schematic side view of an information processing device including a power input connector module in a retracted position and a first power input connector of the power input connector module in a first orientation according to an example of the present disclosure.

FIG. 1B includes a schematic side view of the information processing device of FIG. 1A including the power input connector module in an extended position and the first power input connector in the first orientation according to an example of the present disclosure.

FIG. 1C includes a schematic side view of the information processing device of FIG. 1A including the power input connector module in an extended position and the first power input connector in a second orientation according to an example of the present disclosure.

FIG. 2 includes a perspective view of a power input connector module according to an example of the present disclosure.

FIG. 3 includes a perspective view of a portion of a chassis according to an example of the present disclosure.

FIG. 4 includes a perspective view of a portion of an information processing device having the chassis of FIG. 3, and the power input connector module of FIG. 2 in a retracted position and a first power input connector of the power input connector module in a first orientation according to an example of the present disclosure.

FIG. 5 includes a perspective view of the information processing device of FIG. 4 having the power input connector module in an extended position and the first power input connector in the first orientation according to an example of the present disclosure.

FIG. 6 includes a perspective view of the information processing device of FIG. 5 having the first power input connector detachably mated with a first power source connector of a first external power cord according to an example of the present disclosure.

FIG. 7 includes a perspective view of the information processing device of FIG. 6 having the power input connector module in the extended position and the first power input connector transitioning from the first orientation to a second orientation according to an example of the present disclosure.

FIG. 8 includes a perspective view of the information processing device of FIG. 7 having the power input connector module in the extended position and the first power input connector in the second orientation according to an example of the present disclosure.

FIG. 9 includes a perspective view of the information processing device of FIG. 8 having a second power input connector of the power input connector module detachably mated with a second power source connector of a second external power cord according to an example of the present disclosure.

FIG. 10 includes a perspective view of the information processing device of FIG. 9 having the power input connector module in the extended position and the first power input connector transitioned back to the first orientation from the second orientation according to an example of the present disclosure.

FIG. 11 includes a perspective view of the information processing device of FIG. 10 having the power input connector module transitioned back to the retracted position from the extended position according to an example of the present disclosure.

FIG. 12A includes a perspective front view of an information processing device having a chassis, a power input connector module disposed in the chassis, and a first power supply unit and a second power supply unit both installed in the chassis according to an example of the present disclosure.

FIG. 12B includes a perspective rear view of the information processing device of FIG. 12A having a first external power cord and a second external power cord electrically connected with the first power supply unit and the second power supply unit, respectively, via the power input connector module according to an example of the present disclosure.

FIG. 13 is a flowchart depicting a method of electrically connecting a first external power cord and a second external power cord to a first power supply unit and a second power supply unit, respectively, via a power input connector module of an information processing device according to an example of the present disclosure.

### DETAILED DESCRIPTION

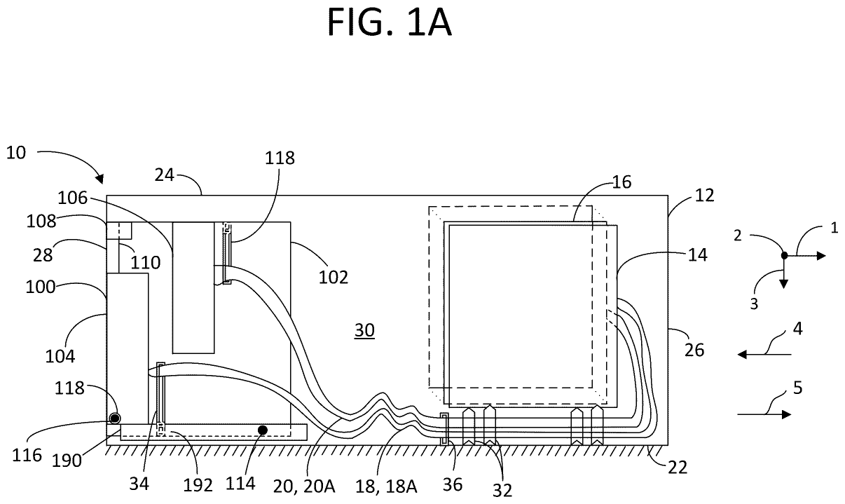

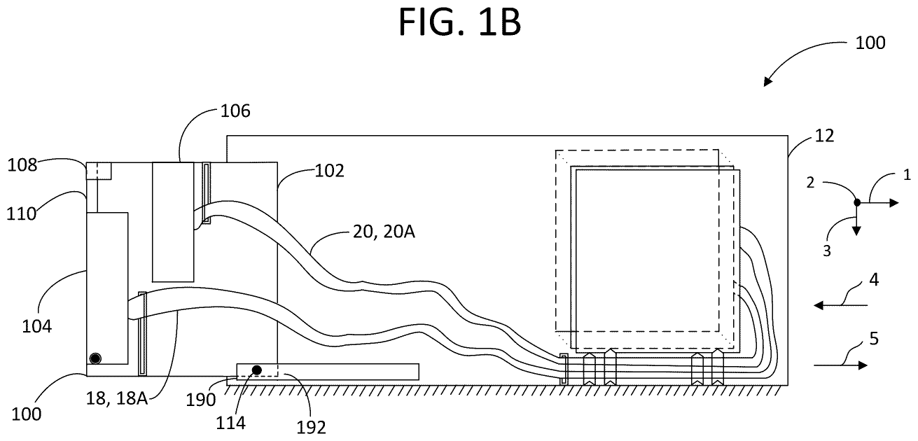

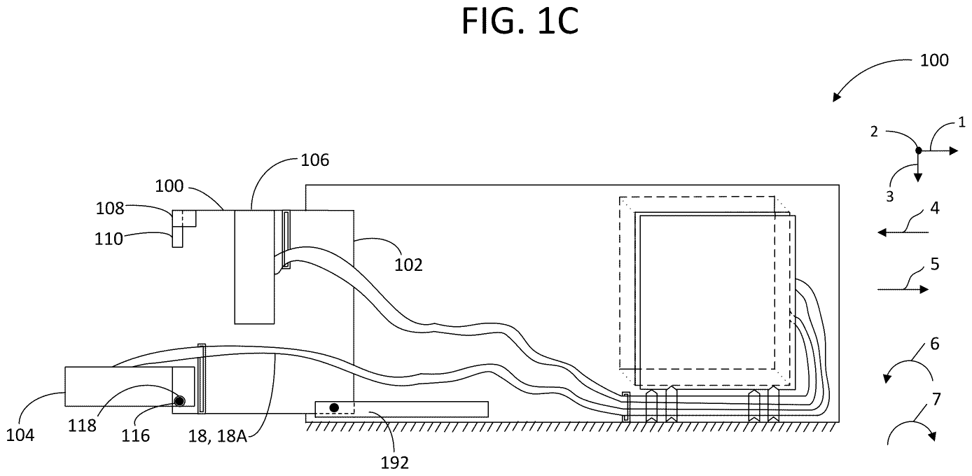

The following detailed description refers to the accompanying drawings. For purposes of explanation, certain examples are described with reference to the components illustrated in FIGS. 1-13. The functionality of the illustrated components may overlap, however, and may be present in a fewer or greater number of elements and components. Moreover, the disclosed examples may be implemented in various environments and are not limited to the illustrated examples. Wherever possible, the same reference numbers are used in the drawings and the following description to refer to the same or similar parts. It is to be expressly understood, however, that the drawings are for the purpose of illustration and description only. While several examples are described in this document, modifications, adaptations, and other implementations are possible. Accordingly, the following detailed description does not limit the disclosed examples. Instead, the proper scope of the examples disclosed may be defined by the appended claims.

An information processing device, such as a computer or networking device, may sometimes include multiple power supply units (PSUs), such as two PSUs, three PSUs, four PSUs, etc. This may be done, in part, to provide redundancy so as to uninterruptedly supply power to electronic components of the information processing device in an event of failure (or during maintenance) of one or more of the power supply units. In addition, systems often also provide multiple power input connectors to allow for multiple power inputs (e.g., power cords) to be connected to the same system, thereby providing redundancy against the failure of one of these external power sources (e.g., if one power cord or the power source connected thereto fails, the system can still draw power from the remaining power cords). In many systems which utilize multiple PSUs, the redundancy in power input connectors is achieved by providing each PSU with its own power input connector, which enables separate power cords to be plugged into each PSU. In such cases, the PSUs are often installed in a cage at the rear of the chassis, with the rear portion of each PSU being located near or forming a part of a rear panel of the chassis such that power input connectors of all the power supply units are positioned in or adjacent the rear panel.

This system design in which power input connectors are at a rear panel of the system can be useful in many common applications where the external power source is located on a rear side of the system and where the rear part of the system can be accessed to plug and unplug power cords. As one example, in many rack-based deployments the information processing devices may be mounted to a rack which usually allows access to both a front and a rear side of the devices. In this arrangement, the rear panel of the chassis is accessible to detachably mate the power input connectors of the power supply units with main power supply connectors of an external power source unit located to the rear of the rack, and thereby electrically connect all the power supply units with the external power source unit.

However, certain information processing devices may be designed for use in deployments in which an external power source will not be located on the rear side of the system and/or the rear panel of the system will not be easily accessible. For example, some systems (such as certain telecommunications or edge servers) are mounted to the wall instead of rack or installed in an equipment cabinet without rear access, and in such cases, the rear panel of the chassis may remain inaccessible for electrically connecting the power supply units with the external power source unit.

One approach to address such issues is to provide a set of power input connectors at a front panel of the chassis and electrically connect these power input connectors to the power supply units, which may be located at the rear of the system, via power transfer cables. This can allow for connection of the system to the external power source unit even if the rear of the system is inaccessible.

However, one challenge with providing power input connectors at the front of the chassis is that, generally, the front panel of the chassis may have insufficient free space in which to accommodate all of the needed power input connectors. Much of the surface area of the front panel is usually occupied by various other components, and after accounting for these other front panel components the remaining free space in the front panel may be sufficient to accommodate one power input connector but may not be sufficient for two or more. In many contexts, it may not be desirable to provide only one power input connector in the front panel because this may remove one important source of redundancy, i.e., redundancy in power inputs. Thus, it may be desired to have at least two power input connectors in the front panel, but as noted above in many systems there is simply not enough unoccupied space in the front panel to allow for this.

A technical solution to the aforementioned problems may include providing at a front panel of the system chassis a power input connector module having a movable member with multiple power input connectors mounted thereto which can be pulled out of the system chassis (like a drawer) to allow access to the power input connectors. The power input connectors are serially spaced apart from one another along a front-rear direction. By stacking the power input connectors serially along the front-rear direction, the footprint of the module on the front panel can be made relatively small (e.g., about the same size as the footprint of one power input connector) even though multiple power input connectors are provided. Furthermore, the ability to pull the movable member forward out of the chassis can allow for all of the power input connectors to be accessed from outside the chassis even though they are serially stacked along the front-rear direction. In particular, in a retracted position of the movable member, a forward-most power input connector (hereinafter, a “first” power input connector) may be located in or adjacent the front panel and may block access to one or more other power input connectors located behind the first power input. However, when the movable member is moved to an extended position, the power input connectors can be arranged so as to allow physical access to the power input connector(s) that is or are disposed serially behind the first power input connector. Additionally, in some examples, the first power input connector is pivotably connected to the movable member so as to provide further clearance to access the other power input connector(s) when the movable member is in the extended position. Accordingly, the power input connector module that is configured to be installed at the front panel may allow to have multiple power input connectors even in space constrained devices which would otherwise have insufficient front panel space to include more than one power input connector.

In some examples, the power input connectors may be electrically connected to corresponding power supply units via respectively corresponding power transfer cables. Thus, when external power cords coupled to one or more external power sources are plugged into the power input connectors, respectively, the power supply units are electrically connected to the one or more external power sources via the power input connector module. In this manner, redundancy in power inputs can be achieved, in addition to redundancy in PSUs, via the power input module.

In some examples, the movable member supports the power input connectors relative to the chassis. Further, the movable member is movably connected to a chassis of an information processing device such that the movable member is movable outside the chassis to an extended position and inside the chassis to a retracted position. In such examples, the power input connectors may travel along with the movable member relative to the chassis as the movable member moves between the extended position and the retracted position. In one or more examples, a guide member may be used to movably connect the movable member to the chassis. In some examples, the guide member may be one component of the chassis. In other examples, the guide member may be one component of the power input connector module. In such examples, the guide member may be coupled to the chassis via fasteners.

Further, in some examples, the first power input connector is pivotably coupled to the movable member such that the first power input connector is rotatable relative to the movable member between a first orientation which is parallel to the axis and a second orientation which is perpendicular to the axis. In some examples, in the first orientation of the first power input connector and in one of the extended position or the retracted position of the movable member, the first power input connector is physically accessible to detachably mate with a first power source connector of a first external power cord. However, in the first orientation of the first power input connector and in the retracted position of the movable member, a second power input connector, rearward of the first power input connector, is positioned within the chassis and is not physically accessible to detachably mate with a second power source connector of a second external power cord. Further, in the second orientation of the first power input connector and in the extended position of the movable member, the second power input connector is physically accessible to detachably mate with a second power source connector of a second external power cord.

In some examples, a portion of each of the power transfer cables may be tied to the movable member and another portion of each of the power transfer cables may be tied to the chassis. In such examples, when the movable member is pulled to the extended position, the portion of each of the power transfer cables is untangled to allow the power input connectors to travel forward along with the movable member. Similarly, when the movable member is pushed to the retracted position the portion of each of the power transfer cables is tangled to allow the first and second power input connectors to travel backward along with the movable member. In one or more examples, the power input connector module may further include a first latch to releasably secure the movable member to the chassis in the retracted position and a second latch to releasably secure the first power input connector to the movable member in the first orientation.

In the description hereinafter, example power input connector module and/or information processing device are described with the help of several views oriented per an axis 1 (or first axis) extending along a horizontal direction, a second axis 2 extending along a lateral direction, and a third axis 3 extending along a vertical direction, which are marked in the respective Figures. Further, the vertical, axial, and lateral directions may be perpendicular to each other and the measurements along the vertical, axial, and lateral directions may be referred to as a height, a width, and a length, respectively. The axes 1, 2, and 3 and directions or positional relationships described herein in relation to these axes are fixed relative to the devices as shown in the figures and not to any external reference frame (such as the ground), and direction terms used herein should be understood in relation to these axes and not to any external reference frame. For example, horizontal and vertical, as used herein, do not refer to orientations relative to the ground.

Referring to the Figures, FIGS. 1A-1C depict a schematic side view of a portion of an information processing device 10 including a power input connector module 100. It should be understood that FIGS. 1A-1C are not intended to illustrate specific shapes, dimensions, or other structural details accurately or to scale, and that implementations of the information processing device 10 and/or the power input connector module 100 and such information processing device 10 and/or power input connector module 100 may have different numbers and arrangements of the illustrated components and may also include other parts that are not illustrated. In the description hereinafter, FIGS. 1A-1C are described concurrently for ease of illustration.

The information processing device 10 may be a computer (e.g., a server, a storage device), a networking device (e.g., a switch, an access point), or the like. In the example of FIGS. 1A-1C, the information processing device 10 is a computer. The information processing device 10 includes a chassis 12, two or more power supply units including at least a first power supply unit 14 and a second power supply unit 16, two or more power transfer cables including at least a first power transfer cable 18 and a second power transfer cable 20, and a power input connector module 100. The information processing device 10 may additionally include various other components including other electronic components such a primary system board (e.g., a mother board), processing resources, memory modules (e.g., DIMMs), storage device, riser cards, and the like. The other electronic components are not shown in the examples of FIGS. 1A-1C merely for the ease of illustration of the essential components of the present disclosure, and such non-disclosure of the other electronic components should not be construed as a limitation of the present disclosure.

As will be described in greater detail below, the power input connector module 100 includes multiple power input connectors. The number of such power input connectors may be any number equal to or greater than two. In some examples, the number of power input connectors matches the number of power supply units in the system. Thus, in some examples, each power supply unit has a corresponding power input connector. In FIGS. 1A-1C, only two of each of these are illustrated and labeled to simplify the drawings.

The chassis 12 may be an enclosure configured to house and provide support to the electronic components of the information processing device 10. In some examples, the chassis 12 may be formed by peripheral sidewalls (not shown), a base 22, a cover 24, a rear panel 26, and a front panel 28. The peripheral sidewalls may be connected to the base 22, the cover 24, the rear panel 26, and the front panel 28 to define an internal volume 30 of the chassis 12 which may be configured to house and provide support to the other components of the information processing device 10.

The power supply units, including at least the first power supply unit 14 and the second power supply unit 16, are hardware devices, each may include electronic elements embedded therein. The power supply units may be configured to receive power from an external power source (not shown) via the power input connector module 100, and the power transfer cables (including the first and second power transfer cables 18, 20), respectively. In such examples, each of the power supply units may be configured to further regulate the received power and supply the regulated power to the electronics components of the information processing device 10. For example, each of the power supply units is configured to convert received AC power into DC power and supply the DC power to the electronic components of the information processing device 10. In the example of FIG. 1A, the power supply units (e.g., the first and second power supply units 14, 16) are disposed adjacent to each other and are positioned next to one of the peripheral sidewalls and the rear panel 26 of the chassis 12. Further, the power supply units are mounted on the base 22 via mounting elements 32. In some examples, one of the power supply units, for example, the second power supply unit 16 may function as a redundant power supply unit of the information processing device 10 in an event of failure (or during maintenance) of the first power supply unit 14, thereby allowing uninterrupted functioning of the information processing device 10.

The power transfer cables, including at least the first power transfer cable 18 and the second power transfer cable 20, are power communication cables, each having a plurality of conductive wires extending between a first end section and a second end section (not labeled) of the power transfer cable. In some examples, each of the power transfer cables are configured to transfer power from a corresponding power input connector of the power input connector module 100 to a corresponding one of the power supply units. For example, the first end section of the first power transfer cable 18 is connected to a first power input connector 104 of the power input connector module 100 and the second end section of the first power transfer cable 18 is connected to the first power supply unit 14. Similarly, the first end section of the second power transfer cable 20 is connected to a second power input connector 106 of the power input connector module 100 and the second end section of the second power transfer cable 20 is connected to the second power supply unit 16. Thus, the first and second power transfer cables 18, 20 may transfer the power from the power input connector module 100 to the first and second power supply units 14, 16. Moreover, if additional power supply units and power input connectors are present, then additional power transfer cables may be used to connect these together in a similar fashion.

The power input connector module 100 may be an interface power module which may be configured to receive power from the external power source and transfer the received power to the power supply units (including first and second power supply units 14, 16) of the information processing device 10 via the power transfer cables (including first and second power transfer cables 18, 20), respectively. In some examples, the power input connector module 100 is disposed at the front panel 28 of the chassis 12. In some examples, the power input connector module 100 includes a movable member 102, and multiple power input connectors including at least a first power input connector 104 and a second power input connector 106. In some examples, the power input connector module 100 may also include a first latch 108, and a second latch 110. Hereinafter, aspects of the power input connector module 100 will be described with reference to the first and second power input connectors 104 and 106 for ease of description. One of ordinary skill in the art having read this disclosure would understand how to extend the principles described herein in relation to the power input connectors 104 and 106 to additional power input connectors.

The movable member 102 is a support structure of the power input connector module 100, which may be configured to support the power input connectors, including the first and second power input connectors 104, 106. In some examples, the movable member 102 is movably connected to the chassis 12, such that the movable member 102 is at least partially movable outside the chassis 12 to an extended position (as shown in FIGS. 1B and 1C) and movable inside the chassis to a retracted position (as shown in FIG. 1A) through the front panel 28. It may be noted herein the retracted position may correspond to a position where the movable member 102 is disposed within the chassis 12, for example, within the front panel 28 of the chassis 12. Similarly, the extended position may correspond to another position where the movable member 102 is partially disposed outside the chassis 12, for example, outside the front panel 28 of the chassis 12.

In one or more examples, the movable member 102 may be movably connected to the chassis 12 via a guide member 190. In certain examples, the guide member 190 may be a component of the chassis 12. In certain other examples, the guide member 190 may be a component of the power input connector module 100. In all such examples, the guide member 190 may be coupled to the base 22 of the chassis 12 via fasteners (not shown). In one or more examples, the guide member 190 includes grooves 192 (only one groove is shown in FIGS. 1A-1C) disposed on its first and second support walls (not labeled) and the movable member 102 includes pins 114 (only one pin is shown in FIGS. 1A-1C) on its first and second sidewalls (not labeled). In such examples, the pins 114 are detachably connected to the grooves 192 so as to movably couple the movable member 102 to the chassis 12 via the guide member 190. In some examples, the guide member 190 may allow the movable member 102 to move along an axis 1 relative to the chassis 12. In particular, the movable member 102 may move in a first direction 4 along the axis 1 to travel from the retracted position to the extended position. Similarly, the movable member 102 may move in a second direction 5 opposite to the first direction 4 along the axis 1 to travel from the extended position to the retracted position.

The power input connectors are mounted to the movable member 102 and disposed in one or more rows of connectors, wherein in each row the connectors are arranged serially (i.e., one-in-front-of-the-other) along the axis 1. A first row of serially stacked connectors includes the first power input connector 104 at a front of the row and the second power input connector 106 disposed behind (rearward of) the first power input connector 104 and aligned with the first power input connector 104 along the axis 1. In some examples, this first row includes just the first and second power input connectors 104 and 106. In other examples, the first row may include additional connectors serially positioned behind the second connectors 106, such as a third connector (not illustrated) behind the second connector, a fourth connector (not illustrated) behind the third connector, and so on.

In some examples, in addition to the first row described above, one or more additional rows of connectors may also be present which are each arranged serially along the axis 1 in parallel to the first row described above. The rows of connectors may be horizontally adjacent to one another in some examples, or vertically adjacent to one another in some examples, or some horizontally adjacent and some vertically adjacent in some examples. Hereinafter, the description will focus primarily on examples which have just the first row of serially disposed power input connectors for convenience, but the principles described herein are also applicable, mutatis mutandis, to examples with multiple parallel rows of power input connectors.

The power input connectors (e.g., the first power input connector 104 and the second power input connector 106) may be configured to interface with power source connectors of external power cords (e.g., a first power source connector of a first external power cord and a second power source connector of a second external power cord) so as to detachably couple the power input connector module 100 with the external power source and receive power from the external power source. In some examples, the power input connectors such as the first power input connector 104 and the second power input connector 106 are disposed serially spaced apart from each other along the axis 1, which is parallel to the first and second directions 4, 5 of movement of the movable member 102 relative to the chassis 12. Further, the first and second power input connectors 104, 106 are coupled to the chassis 12 via the movable member 102. More particularly, the movable member 102 provides support to the first and second power input connectors 104, 106. In one or more examples, the first power input connector 104 is pivotably coupled to the movable member 102 such that the first power input connector 104 is rotatable relative to the movable member 102 between a first orientation (as shown in FIGS. 1A-1B) parallel to the axis 1 and a second orientation (as shown in FIG. 1C) perpendicular to the axis 1. It may be noted herein that the first orientation may correspond to an orientation of the first power input connector 104 which is parallel to the axis 1. Similarly, the second orientation may correspond to another orientation of the first power input connector 104 which is perpendicular to the axis 1. In particular, the first power input connector 104 includes pivot pins 116 (only one pin is shown in the examples of FIGS. 1A-1C) and the movable member 102 includes recesses 118 (only one recess is shown in the examples of FIGS. 1A-1C). In such examples, the pivot pins 116 are engaged with the recesses 118 so as to pivotably couple the first power input connector 104 with the movable member 102. In one or more examples, the second power input connector 106 is fixedly coupled to the movable member 102 such that the second power input connector 106 is oriented along the first orientation.

In some examples, each of the first and second power input connectors 104, 106 may have a socket housing configured to receive a plug housing of corresponding first and second power source connectors of the first and second external power cords, respectively, and detachably couple the power input connector module 100 with the external power source. In such examples, each of the first and second power input connectors 104, 106 and each of the first and second power source connectors may include electrical conductors, which in the coupled state of the power input connector module 100 with the power source connectors, may establish electrical connection therebetween to supply power from the external power source to the power input connector module 100.

As noted above, in some examples the first and second latches 108 and 110 are optionally included. Each of the first latch 108 and second latch 110 is a lock member, such as a cam latch, draw latch, spring latch, or the like. In one or more examples, the first latch 108 may be coupled to the first sidewall of the movable member 102 and configured to releasably secure the movable member 102 to the chassis 12. Referring to FIG. 1, in the first orientation of the first power input connector 104 and in the retracted position of the movable member 102, the first latch may be configured to secure the movable member 102 to the chassis 12. Similarly, the second latch 110 may be coupled to the second sidewall of the movable member 102 and configured to releasably secure the first power input connector 104 to the chassis 12.

The information processing device 10 may further include, in some examples, first clips 34 configured to tie a section e.g., the first end section of the first and second power transfer cables 18, 20 to the movable member 102 and a second clip 36 configured to tie another section, e.g., a mid-section of the first and second power transfer cables 18, 20 to the chassis 12 so as to allow the portion of the first and second power transfer cables 18, 20 to tangle and untangle when the movable member 102 is moved between the retracted position and extended position. In some examples, the portion of the first and second power transfer cables 18, 20 may correspond to the section of the first and second power transfer cables 18, 20 located between the first clips 34 and the second clip 36.

In the example of FIG. 1A, the movable member 102 is in the retracted position, i.e., the movable member 102 is disposed inside the front panel 28 and positioned within the chassis 12. Similarly, the first power input connector 104 is in the first orientation, i.e., the first power input connector 104 is oriented parallel to the axis 1. In such examples, in the first orientation of the first power input connector 104 and in the retracted position of the movable member 102, the first power input connector 104 may be physically accessible to detachably mate with the first power source connector of the first external power cord. It may be noted herein that the term physically accessible may refer to ease of access to the first and/or second power input connectors 104, 106 of the power input connector module 100 without the use of any tools for detachably mating with the first and/or the second power source connectors. In such examples, in the first orientation of the first power input connector 104 and in the retracted position of the movable member 102, the second power input connector 106 may be positioned within the chassis and may not be physically accessible to detachably mate with a second power source connector of a second external power cord.

FIG. 1B includes the power input connector module 100 of FIG. 1A transitioned from the retracted position to the extended position. In some examples, the first latch 108 is released before transitioning the power input connector module 100 from the retracted position to the extended position. For example, the first latch 108 is actuated first to release the movable member 102 from the chassis 12. The movable member 102 is later moved (e.g., slide) relative to the chassis 12 in a first direction 4 along an axis 1 so as to transition the movable member 102 from the retraction position (as shown in FIG. 1A) to the extended position (as shown in FIG. 1B). In some examples, the grooves 192 of the guide member 190 may allow the pins 114 of the movable member 102 to slide, thereby allowing the movable member 102 to move relative to the chassis 12 in the first direction 4 along the axis 1. The first and second latches 108, 110 which are coupled to the movable member 102 also travel along with the movable member 102. Additionally, the first and second power input connectors 104, 106 which are supported by the movable member 102 also travel along with the movable member 102 relative to the chassis 12 as the movable member 102 moves from the retracted position to the extended position. As the movable member 102 moves from the retracted position to the extended position, the portion 18A, 20A of each of the first and second power transfer cables 18, 20 is untangled to allow the first and second power input connectors 104, 106 to travel forward along with the movable member 102. The movement of the movable member 102 to the extended position allows for the power input connectors located behind the front power connectors to become accessible from outside the chassis, e.g., to plug in or unplug a power cord.

In some examples, when the power input connector module 100 is in the extended position as illustrated in FIG. 1B, each of the first and second power input connectors 104, 106 is oriented in the first orientation, which is parallel to the axis 1. The orientation of a power input connector refers to a direction pointing away from the connector along a mating axis of the connector, wherein the mating axis refers to an axis along which the power input connector and/or a complementary connector would move while mating with one another. In some examples, in the first orientation of the first power input connector 104 and in the extended position of the movable member 102, the first power input connector 104 is physically accessible to detachably mate with a first power source connector of a first external power cord (not shown). In some examples, the rearward power connectors (such as the second power connector 106) are also accessible in this state. However, in some examples, in this state the rearward power connectors may be difficult to access. In particular, in some examples, in the first orientation of the first power input connector 104 and in the extended position of the movable member, the second power input connector is either not physically accessible to detachably mate with the second power source connector of a second external power cord or is inconvenient to access. Thus, in some examples, some of the power connectors, such as the first power connector 104, are configured to be movable relative to the movable member 102 to allow for the connector to be further moved out of the way allowing for even easier access to the rearward power connectors. In some examples, this movement of the forward power connector(s) relative to the movable member 102 includes rotating/pivoting the forward power connector(s) relative to the movable member 102. In some examples, this rotation/pivoting is about a horizontal axis (such as an axis parallel to axis 1 or axis 2), while in other examples the rotation/pivoting is about a vertical axis (parallel to axis 3). FIG. 1C illustrates one non-limiting example in which the first connector 104 is pivotable about a horizontal axis parallel to axis 2

FIG. 1C includes the first power input connector 104 of the power input connector module 100 of FIG. 1B, transitioned from the first orientation to the second orientation. In some examples, the second latch 110 is released before transitioning the first power input connector 104 from the first orientation to the second orientation. For example, the second latch 110 is actuated first to release the first power input connector 104 from the movable member 102. The first power input connector 104 is rotated relative to the movable member 102 along a third direction 6 so as to transition the first power input connector 104 from the first orientation (as shown in FIG. 1B) to the second orientation (as shown in FIG. 1C) which is perpendicular to the axis 1. In some examples, the pivot pins 116 of the first power input connector 104 which are engaged with the recesses 118 of the movable member 102 may allow the first power input connector 104 to pivot from the first orientation to the second orientation. However, the second power input connector 106 which is fixedly attached to the movable member 102 may stay in the first orientation which is parallel to the axis 1. In some examples, as the first power input connector 104 rotates from the first orientation to the second orientation, the portion 18A of the first power transfer cable 18 may further untangle to allow such rotation of the first power input connector 104 relative to the power input connector module 100. Accordingly, in the second orientation of the first power input connector 104 and in the extended position of the movable member 102, the second power input connector 106 is physically accessible to detachably mate with a second power source connector of a second external power cord (not shown).

Even though not illustrated, the first power input connector 104 of the power input connector module 100 of FIG. 1C may be further transitioned from the second orientation to the first orientation. For example, the first power input connector 104 may be further rotated relative to the movable member 102 along a fourth direction 7 so as to transition the first power input connector 104 from the second orientation (as shown in FIG. 1C) to the first orientation (as shown in FIG. 1B) which is parallel to the axis 1. In such examples, as the first power input connector 104 is transitioned to the first orientation, the second latch 110 automatically secures the first power input connector 104 to the second sidewall of the movable member 102. Further, the power input connector module 100 may be transitioned from the extended position to the retracted position. The movable member 102 is moved (e.g., slide) relative to the chassis 12 in the second direction 5 along the axis 1 so as to transition the movable member 102 from the extended position (as shown in FIG. 1B) to the retracted position (as shown in FIG. 1A). In such examples, as the power input connector module 100 is transitioned to the retracted position, the first latch 108 automatically secures the power input connector module 100 to the chassis 12.

Since the power input connector module 100 has been designed such that the movable member 102 is movable outside and inside the information processing device 10 relatively to the chassis 12 and the first power input connector is rotatable relative to the movable member 102, such a design of the power input connector module 100 may allow the first and second power input connectors 104, 106 to be disposed serially along the axis 1 (longitudinal or horizontal direction) and occupy relatively less lateral space at the front panel 28 of the chassis. In other words, the power input connector module 100 may not occupy relatively large lateral space at the front panel 28 of the chassis.

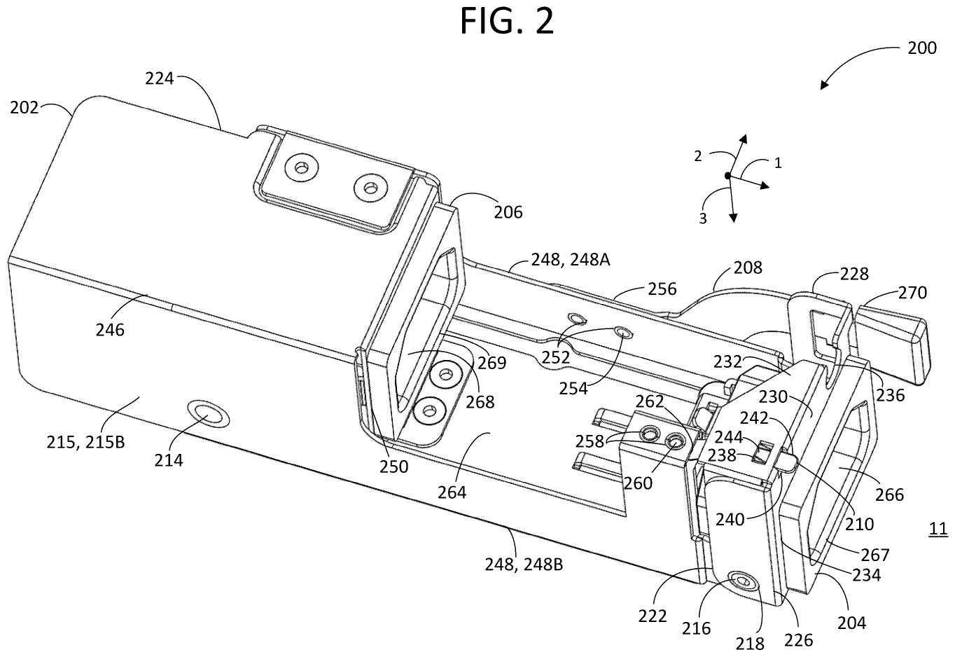

FIG. 2 depicts a perspective view of a power input connector module 200. In some examples, the power input connector module 200 includes a movable member 202, a first power input connector 204, a second power input connector 206, a first latch 208, and a second latch 210.

The movable member 202 includes a first support portion 222 and a second support portion 224. In one or more examples, the first support portion 222 is pivotably coupled to the second support portion 224 such that the first support portion 222 can rotate relative to the second support portion 224 between a first orientation and a second orientation.

The first support portion 222 includes a first sidewall portion 226, a second sidewall portion 228 opposite to the first sidewall portion 226, a front wall portion 230, and a cover portion 232 disposed between the first and second sidewall portions 226, 228 and coupled to the first and second sidewall portions 226, 228 and the front wall portion 230. The first and second sidewall portions 226, 228 are disposed spaced apart from each other. Further, each of the first and second sidewall portions 226 228 includes a pivot pin 216 configured to engage with a corresponding recess 218 of the second support portion 224 such that the first support portion 222 is pivotably coupled to the second support portion 224. The front wall portion 230 includes a first housing recess 234 configured to receive and support the first power input connector 204. The front wall portion 230 further includes a cord opening 236 configured to allow a second external cord 900 to extend between an external environment 11 and the second support portion 224 via the first support portion 222. Further, the front wall portion 230 includes a cut-out 240 to allow a free end portion 242 of the second latch 210 to extend therethrough and move up and down relative to the cover portion 232. The cover portion 232 includes a second locking groove 238 configured to engage with a second locking protrusion 244 formed in the free end portion 242 of the second latch 210 to releasably secure the first support portion 222 to the second support portion 224. In the example of FIG. 2, the first support portion 222 is positioned in the first orientation.

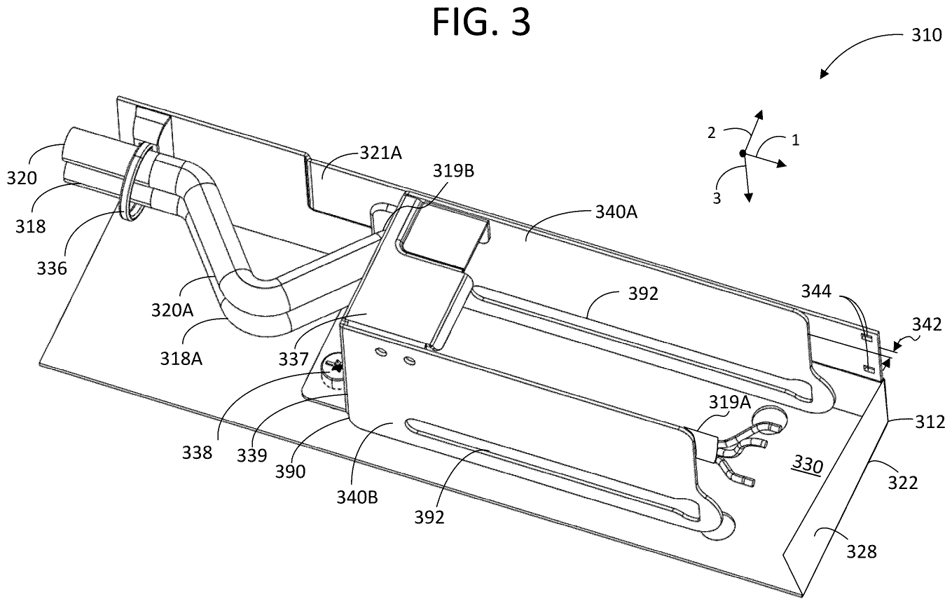

The second support portion 224 includes an enclosure 246, and arms 248. The enclosure 246 includes a second housing recess 250 configured to receive and support the second power input connector 206. Further, the enclosure 246 is configured to house a portion of each of the first and second power transfer cables 318, 320 (as shown in FIG. 3) and allow the portion of the first power transfer cable 318 to extend into a space 264 defined between the arms 248. The enclosure 246 may include pins 214 extending inwards from both sides 215 (only one side 215B is shown) along a second axis 2. In some examples, the pins 214 are configured to engage with grooves 392 (as shown in FIG. 3) of a guide member 390 (as shown in FIG. 3) so as to allow the movable member 202 (as shown in FIG. 2) to slide along the axis 1 between a retracted position and an extended position. In some examples, the arms 248 are spaced apart from one another and extend from both sides 215 of the enclosure 246 along the axis 1. The arms 248 are configured to further house the portion of the first power transfer cable 318 extended from the enclosure 246. In some examples, a first arm 248A among the arms 248 includes first mounting elements 252 engaged with first complementary mounting elements 254 of the first latch 208 to rigidly couple a fixed end portion 256 of the first latch 208 to the movable member 202. Similarly, a second arm 248B among the arms 248 includes second mounting elements 258 engaged with second complementary mounting elements 260 of the second latch 210 to rigidly couple a fixed end portion 262 of the second latch 210 to the movable member 202.

The first power input connector 204 includes a first socket housing 266 and conductors (not shown). The first socket housing 266 includes a first end 267 facing the external environment 11 and configured to receive and detachably mate with a first plug housing 504 of a first power source connector 502. The first socket housing 266 further includes a second end (not shown) opposite the first end 267, facing the second support portion 224, and configured to receive the portion of the first power transfer cable 318. The conductors are disposed within the first socket housing 266 and configured to electrically connect the portion of the first power transfer cable 318 with the first power source connector 502, and thereby allow transfer of power from the first power source connector 502 to the first power input connector 204. The first power input connector 204 is disposed in the first housing recess 234 and coupled to the front wall portion 230 of the first support portion 222. In some examples, the first power input connector 204 rotates along with the first support portion 222 when the first support portion 222 rotates relative to the second support portion 224 between the first orientation and the second orientation.

The second power input connector 206 includes a second socket housing 268 and conductors (not shown). The second socket housing 268 includes a first end 269 facing the first power input connector 204 and configured to receive and detachably mate with a second plug housing 904 of a second power source connector 902. The second socket housing 268 further includes a second end (not shown) opposite the first end 269, facing the enclosure 246 of the second support portion 224, and configured to receive the portion of the second power transfer cable 320. The conductors are disposed within the second socket housing 268 and configured to electrically connect the portion of the second power transfer cable 320 with the second power source connector 902, and thereby allow transfer of power from the second power source connector 902 to the second power input connector 206. The second power input connector 206 is disposed in the second housing recess 250 and coupled to the enclosure 246 of the second support portion 224. In some examples, the second power input connector 204 is fixedly attached to the second support portion 224 and is oriented along the first orientation. In one or more examples, the first power input connector 204 and the second power input connector 206 both are disposed serially spaced apart from each other along the axis 1. In other words, the first and second power input connectors 204, 206 are disposed spaced apart from each other by a distance which is substantially equal to a length of the arms 248.

In some examples, each of the first and second power input connectors 204, 206 is one of a socket connector or a plug connector. In such examples, each of first and second power source connectors 502, 902 of the first and second external power cords 500, 900, respectively, is another one of the socket connector or the plug connector.

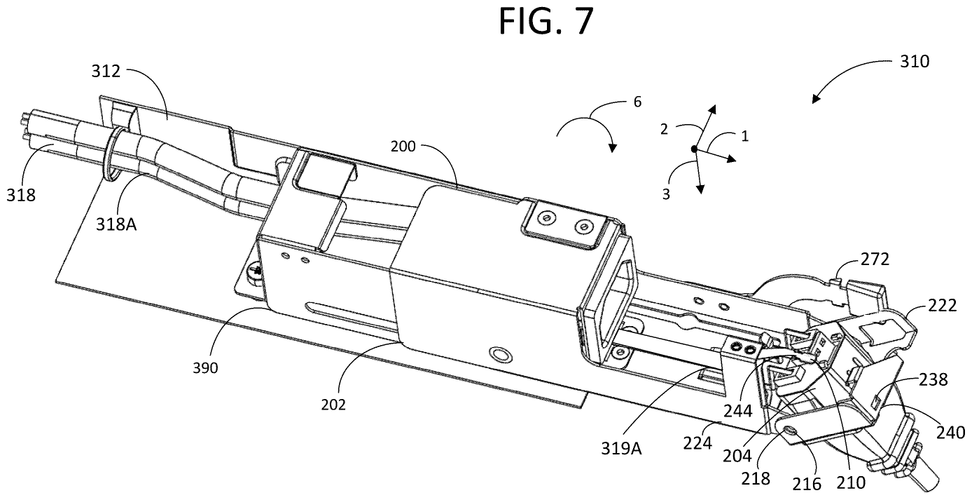

The first latch 208 includes a free end portion 270 and a fixed end portion 256. In some examples, the fixed end portion 256 has first complementary mounting elements 254 which are fixedly attached to the first mounting elements 252 of the first arm 248A so as to couple the first latch 208 to the movable member 202. The free end portion 270 includes first locking protrusions 272 (as shown in FIG. 7) which are configured to engage with first locking grooves 344 (as shown in 3) of a chassis 312 to releasably secure the movable member 202 to the chassis 312.

The second latch 210 includes a free end portion 242 and a fixed end portion 262. In some examples, the fixed end portion 262 has second complementary mounting elements 260 which are fixedly attached to the second mounting elements 258 of the second arm 248B so as to couple the second latch 210 to the movable member 202. The free end portion 242 includes a second locking protrusion 244 which is configured to engage with the second locking groove 238 of the movable member 202 e.g., the cover portion 232 of the first support portion 222 to releasably secure the first support portion 222 of the movable member 202 with the second support portion 224 of the movable member 202.

FIG. 3 depicts a perspective view of a portion of an information processing device 310 including a chassis 312, a first power transfer cable 318, and a second power transfer cable 320. In some examples, the information processing device 310 further includes a guide member 390.

The chassis 312 includes a peripheral sidewall 321A, a base 322, a cover (not shown), a rear panel (not shown), and a front panel 328 (only a portion of the front panel 328 is shown in FIG. 3 for ease of illustration). The peripheral sidewall 321A is connected to the base 322 to define an internal volume 330 of the chassis 312 to house and provide support to electronic components of the information processing device 310. The peripheral sidewall 321A includes first locking grooves 344 configured to engage with the first locking protrusions 272 of the first latch 208 to releasably secure the movable member 202 to the chassis 312.

The guide member 390 includes a partial cover wall 337, a rear wall 339, a first support wall 340A, and a second support wall 340B. In some examples, the first and second support walls 340A, 340B are disposed spaced apart from each other and coupled to the partial cover wall 337 and the rear wall 339. Further, the rear wall 339 includes a cable opening (not shown) to allow the first and second power transfer cables 318, 320 to extend therethrough. The guide member 390 is mounted on the base 322 and the rear wall 339 of the guide member 390 is coupled to the base 322 via fasteners 338. In some examples, the guide member 390 is positioned adjacent to the peripheral sidewall 321A and the front panel 328. In particular, the first support wall 340A of the guide member 390 is positioned adjacent to the peripheral sidewall 321A such that a gap 342 is defined therebetween so as to allow the first arm 248A of the movable member 202 (as shown in FIG. 2) and the fixed end portion 256 (as shown in FIG. 2) of the first latch 208 (as shown in FIG. 2) may be disposed along the gap 342. The guide member 390 further includes grooves 392 formed on the first and second support walls 340A, 340B, each extending along the axis 1. The grooves 392 may engage with the pins 214 (as shown in FIG. 2) of the movable member 202 so as to movably couple the movable member 202 to the chassis 312 via the guide member 390 and allow the movable member 202 to move between a retracted position and an extended position. In other words, the guide member 390 may allow the movable member 202 to move along the axis 1 relative to the chassis 312.

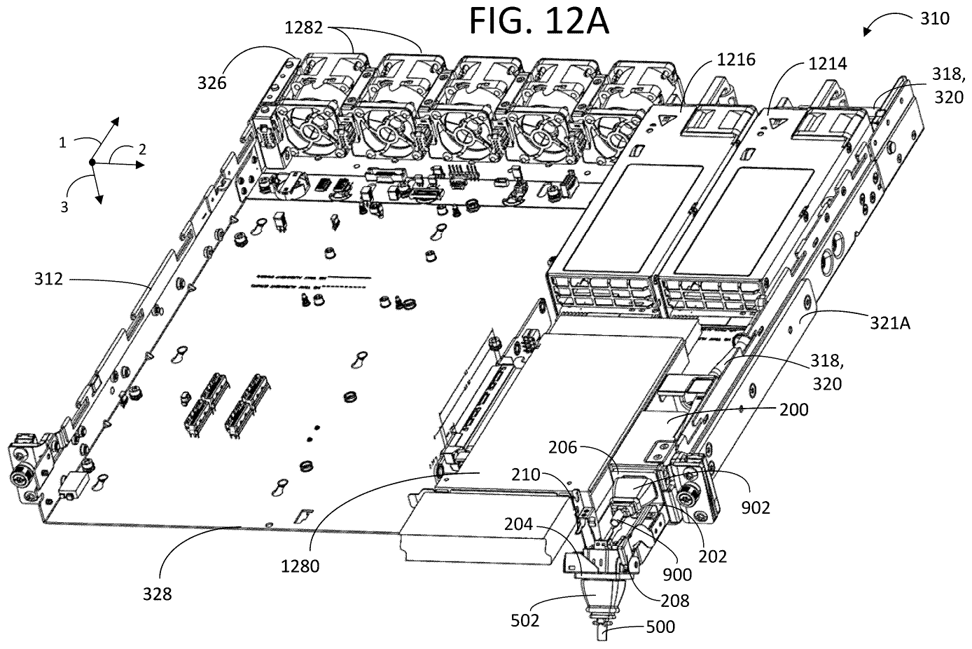

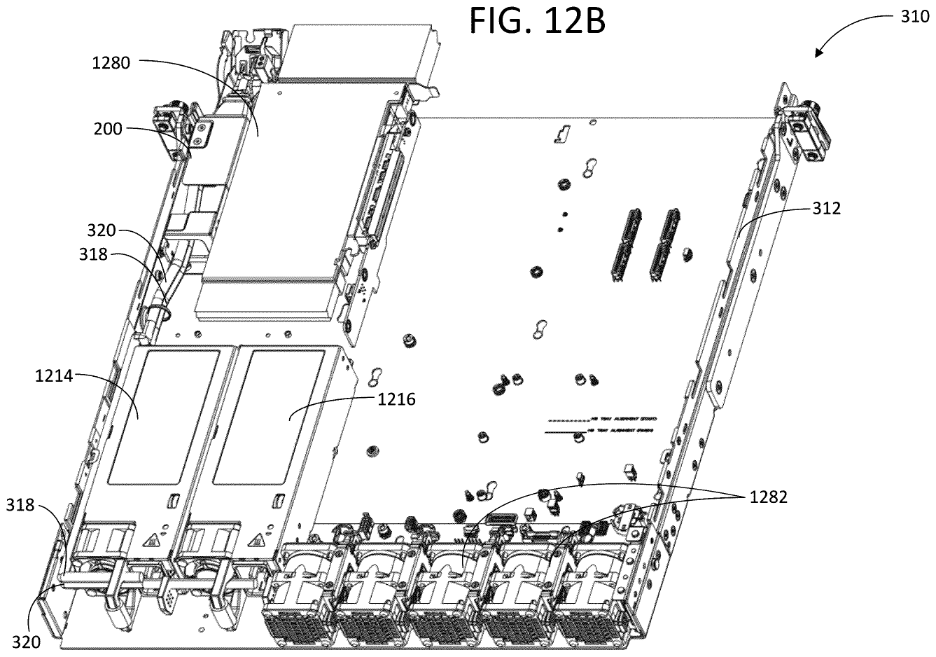

Each of the first power transfer cable 318 and the second power transfer cable 320 may have a plurality of conductive wires disposed therein between a first end section 319A, 319B and a second end section (not labeled) of the respective first and second power transfer cables 318, 320. Further, each of the first and second power transfer cables 318, 320 may be configured to transfer power from the power input connector module 200 (as shown in FIG. 2) to first and second power supply units 1214, 1216, respectively (as shown in FIGS. 12A and 12B). In particular, the first end section 319A of the first power transfer cable 318 may be connected to the first power input connector 204 (as shown in FIG. 2) of the power input connector module 200 and the second end section of the first power transfer cable 318 may be connected to the first power supply unit 1214. Similarly, the first end section 319B of the second power transfer cable 320 may be connected to the second power input connector 206 (as shown in FIG. 3) of the power input connector module 200 and the second end section of the second power transfer cable 320 may be connected to the second power supply unit 1216. Thus, the first and second power transfer cables 318, 320 may transfer the power from the power input connector module 200 to the first and second power supply units 1214, 1216.

The information processing device 10 further includes first clips (not shown) configured to tie a section e.g., the first end section 319A, 319B of the first and second power transfer cables 318, 320 to the movable member 202 and a second clip 336 configured to tie another section, e.g., a mid-section of the first and second power transfer cables 318, 320 to the chassis 312 so as to allow portions 318A, 318B of the first and second power transfer cables 318, 320 to tangle and untangle when the movable member 202 is moved between the retracted position and the extended position. In some examples, the portion 318A, 320B of the first and second power transfer cables 318, 320 may correspond to the section of the first and second power transfer cables 318, 320 located between the first clips 334 and the second clip 336.

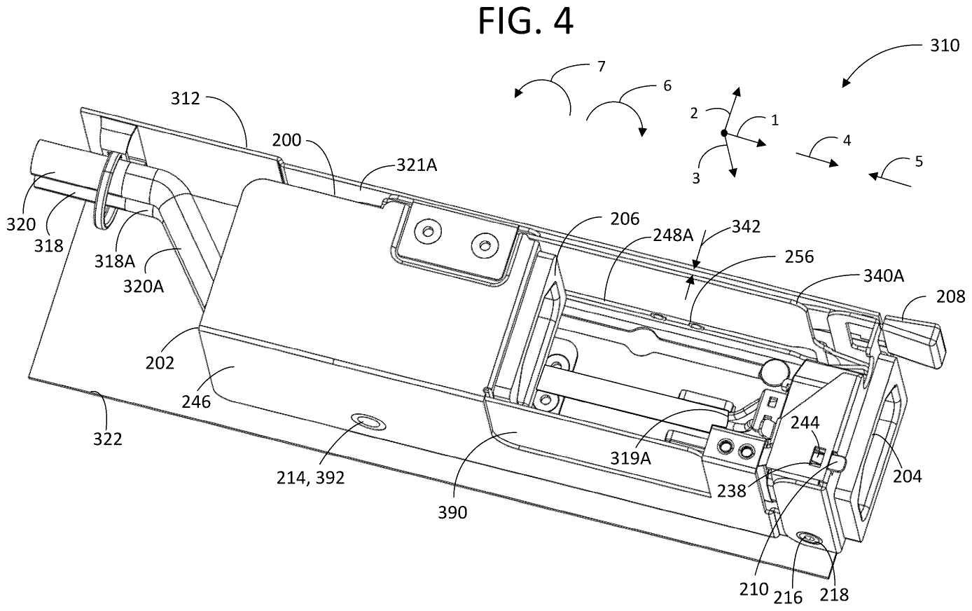

FIG. 4 depicts a perspective view of a portion of an information processing device 310 having the chassis 312 of FIG. 3, and the power input connector module 200 of FIG. 2. In some examples, the power input connector module 200 is disposed on the guide member 390 such that the pins 214 of the movable member 202 are engaged with the grooves 392 of the guide member 390, the enclosure 246 of the movable member 202 houses the portion 318A, 320A of the first and second power transfer cables 318, 320, the rear wall 339 and the partial cover wall 337 of the guide member 390, and the first arm 248A and the fixed end portion 256 of the first latch 208 is disposed along the gap 342 defined between the first support wall 340A of the guide member 390 and the peripheral sidewall 321A of the chassis 312. Further, the first end section 319A of the first power transfer cable 318 is coupled to the first power input connector 204. Similarly, the first end (not shown) of the second power transfer cable 320 is coupled to the second power input connector 206.

The first locking protrusions 272 of the first latch 208 are engaged with the first locking grooves 344 of the peripheral sidewall 321A of the chassis 312 to releasably secure the movable member 202 to the chassis 312. Accordingly, in such examples, the first latch 208 retains the movable member 202 in a retracted position. However, when the first latch 208 is actuated, it may release the movable member 202 so as to allow the movable member 202 to move from the retracted position to an extended position. In one or more examples, the movable member 202 moves partially outside the chassis 312 to the extended position and inside the chassis 312 to the retracted position. In such examples, the first and second power input connectors 204, 206 which are supported by the movable member 202 may also travel along with the movable member 202 relative to the chassis 312 as the movable member 202 moves between the extended position and the retracted position. In particular, the movable member 302 may move in a first direction 4 along the axis 1 to travel from the retracted position to the extended position. Similarly, the movable member 302 may move in a second direction 5 opposite to the first direction 4 along the axis 1 to travel from the extended position to the retracted position. In the example of FIG. 4, the movable member is in the retracted position.

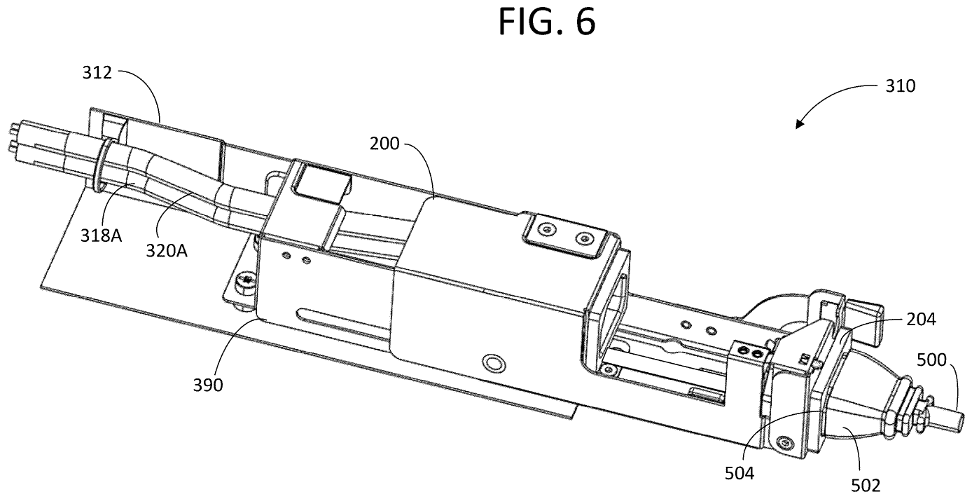

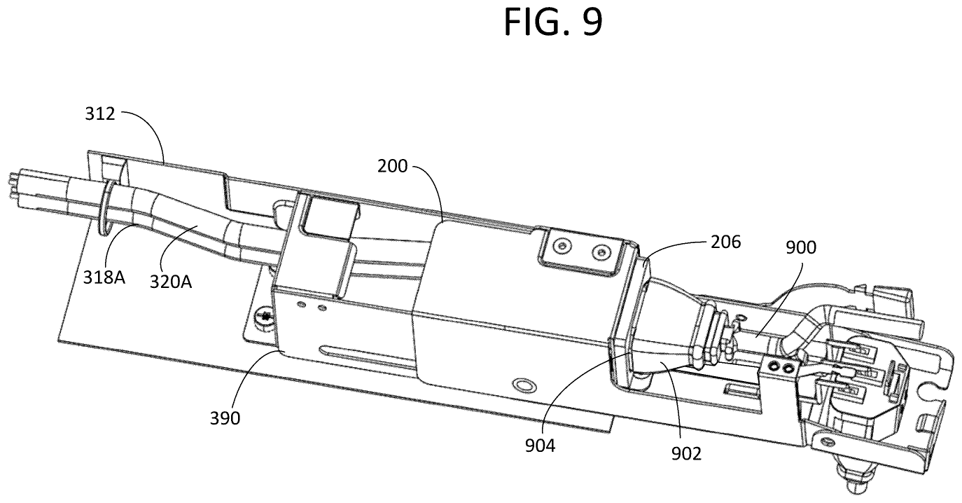

The second locking protrusion 244 of the second latch 210 is engaged with the second locking groove 238 of the movable member 202 to releasably secure the first power input connector 204 to the movable member 202. Accordingly, in such examples, the second latch 210 retains the first power input connector 204 in a first orientation. However, when the second latch 210 is actuated, it may release the first power input connector 204 so as to allow the first power input connector 204 to rotate from the first orientation to a second orientation. In particular, the first power input connector 204 may rotate in a third direction 6 relative to the movable member 202 to move from the first orientation to the second orientation. Similarly, the first power input connector 204 may rotate in a fourth direction 7 relative to the movable member 202 to move from the second orientation to the first orientation. In some examples, the first orientation may correspond to the position which is parallel to the axis 1. Similarly, the second orientation may correspond to the position which is perpendicular to the axis 1. In the example of FIG. 4, the movable member 202 is in the retracted position and the first power input connector 204 is in the first orientation. In the first orientation of the first power input connector 204 and in retracted position of the movable member 202, the first power input connector 204 is physically accessible to detachably mate with a first power source connector 502 of a first external power cord 500 (as shown in FIG. 6). In one or more examples, in the first orientation of the first power input connector 204 and in the retracted position of the movable member 202, the second power input connector 206 is positioned within the chassis 312 and is not physically accessible to detachably mate with a second power source connector 902 of a second external power cord 900 (as shown in FIG. 9).

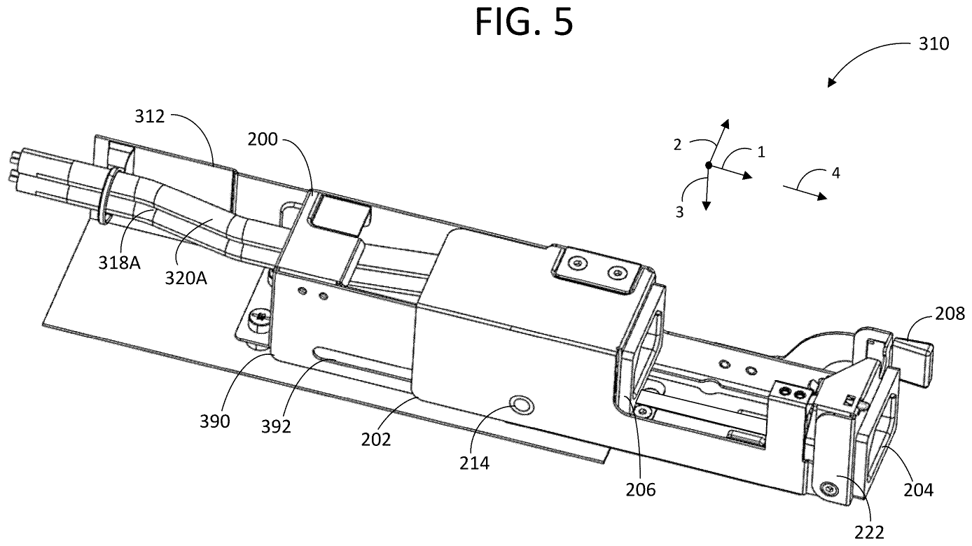

FIG. 5 depicts a perspective view of the information processing device 310 of FIG. 4 having the power input connector module 200 in an extended position and the first power input connector 204 in the first orientation. In some examples, the first latch 208 is actuated to release the movable member 202 from the chassis 312. In particular, the first latch 208 is pushed along a second axis to disengage the first locking protrusions 272 (as shown in FIG. 7) from the first locking grooves 344 (as shown in FIG. 3) and thereby release the movable member 202 from the chassis 312. Further, the first support portion 222 of the movable member 202 is pulled in the first direction 4 along the axis 1 so as to move the movable member 202 from the retracted position to the extended position. In such examples, the pins 214 of the movable member 202 slides along the grooves 392 of the guide member 390 to allow the movable member 202 to move from the retracted position to the extended position. In such examples, the first and second power input connectors 204, 206 and the portion 318A, 320A of each of the first and second power transfer cables 318, 320 travel along with the movable member 202 relative to the chassis 312 as the movable member moves from the retracted position to the extended position. In some examples, the portion 318A, 320A of each of the first and second power transfer cables 318, 320 is untangled to allow the first and second power input connectors 204, 206 to travel forward along with the movable member 202. In the example of FIG. 4, the movable member 202 is in the extended position and the first power input connector 204 is in the first orientation. In the first orientation of the first power input connector 204 and in extended position of the movable member 202, the first power input connector 204 is physically accessible to detachably mate with a first power source connector 502 of a first external power cord 500 (as shown in FIG. 6). In one or more examples, in the first orientation of the first power input connector 204 and in the extended position of the movable member 202, the second power input connector 206 is adjacent to the front panel (not labeled) of the chassis 312 and is not physically accessible to detachably mate with a second power source connector 902 of a second external power cord 900 (as shown in FIG. 9).

FIG. 6 depicts a perspective view of the information processing device 310 of FIG. 5 having the first power input connector 204 detachably mated with a first power source connector 502 of a first external power cord 500. In some examples, the first external power cord 500 may be electrically connected to an external power source unit (not shown) and the first power source connector 502. In some examples, the first power source connector 502 includes a first plug housing 504 which has a complementary profile to that of a first socket housing 266 (as shown in FIG. 2) of the first power input connector 204. Thus, the first socket housing 266 of the first power input connector 204 may be able to receive and detachably mate with the first plug housing 504 of the first power source connector 502, and electrically connect the power input connector module 200 with the external power source unit via the first power input connector 204, the first power source connector 502, and the first external power cord 500. Accordingly, the first external power cord 500 may be configured to supply power from the external power source unit to the power input connector module 200.

FIG. 7 depicts a perspective view of the information processing device 310 of FIG. 6 having the power input connector module 200 in the extended position and the first power input connector 204 transitioning from the first orientation to a second orientation. In some examples, the second latch 210 is actuated to release the first power input connector 204 from the movable member 202. In particular, the second latch 210 is pulled downwards along a third axis 3 to disengage the second locking protrusion 244 from the second locking groove 238 and thereby release the first power input connector 203 from the movable member 202. In particular, the second latch 210 is actuated to release the first support portion 222 of the movable member 202 supporting the first power input connector 204 from the second support portion 224 of the movable member 202 supporting the second power input connector 206. Further, the first support portion 222 of the movable member 202 is rotated along the third direction 4 so as to move the first power input connector 204 from the first orientation towards the second orientation. In such examples, the pivot pins 216 of the first support portion 222 which are engaged with the recesses 218 of the second support portion 224 may allow the first power input connector 204 to pivot from the first orientation towards the second orientation. In such examples, the first power transfer cable 318 may further move along with the first power input connector 204 relative to the second support portion 224 as the first support portion 222 moves from the first orientation towards the second orientation. In some examples, the portion 318A of the first power transfer cable 318 is further untangled to allow the first power input connector 204 to move towards the second orientation.

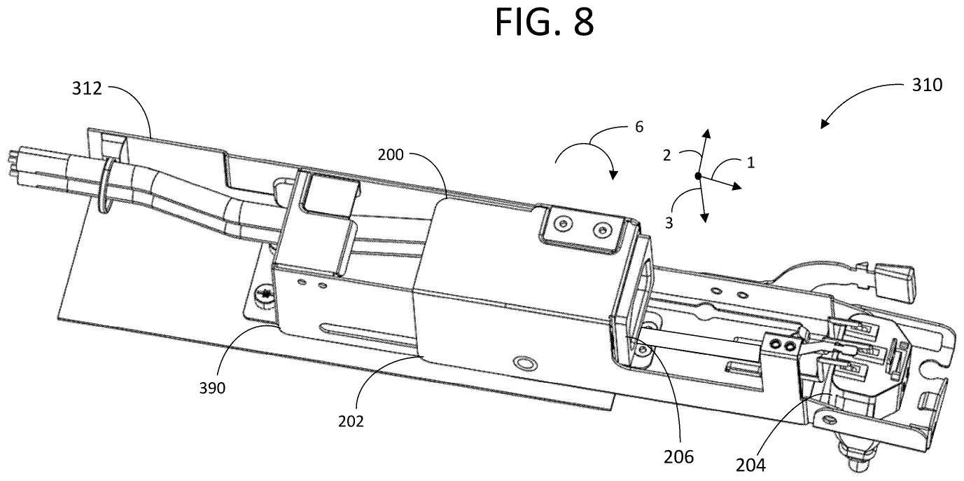

FIG. 8 depicts a perspective view of the information processing device 310 of FIG. 7 having the power input connector module 200 in the extended position and the first power input connector 204 in the second orientation. In some examples, the first support portion 222 continues to rotate along the third direction 6 and moves the first power input connector 204 to the second orientation. In some examples, the second orientation corresponds to the position of the first power input connector 204 which is perpendicular to the axis 1. In some examples, the first support portion 222 in the second orientation may allow physical access to the second power input connector 206, which is otherwise disposed within the chassis 312 and not accessible from the front panel. In the second orientation of the first power input connector 204 and in the extended position of the movable member 202, the second power input connector 206 may be physically accessible to detachably mate with a second power source connector 902 of a second external power cord 900 (as shown in FIG. 9).

FIG. 9 depicts a perspective view of the information processing device 310 of FIG. 8 having the second power input connector 206 detachably mated with a second power source connector 902 of a second external power cord 900. In some examples, the second external power cord 900 may be electrically connected to the external power source unit and the second power source connector 902. In such examples, the second power source connector 902 includes a second plug housing 904 which has a complementary profile to that of a second socket housing 268 (as shown in FIG. 2) of the second power input connector 206. Thus, the second socket housing 268 of the second power input connector 206 may be able to receive and detachably mate with the second plug housing 904 of the second power source connector 902, and electrically connect the power input connector module 200 with the external power source unit via the second power input connector 206, the second power source connector 902, and the second external power cord 900. In some examples, detachably mating the second power source connector 902 of the second external power cord with the second power input connector 206 includes moving an end (not labeled) of the second external power cord 900 past the first power input connector 204 while the first power input connector 204 is in the second orientation. Accordingly, the second external power cord 900 may be configured to supply power from the external power source unit to the power input connector module 200.

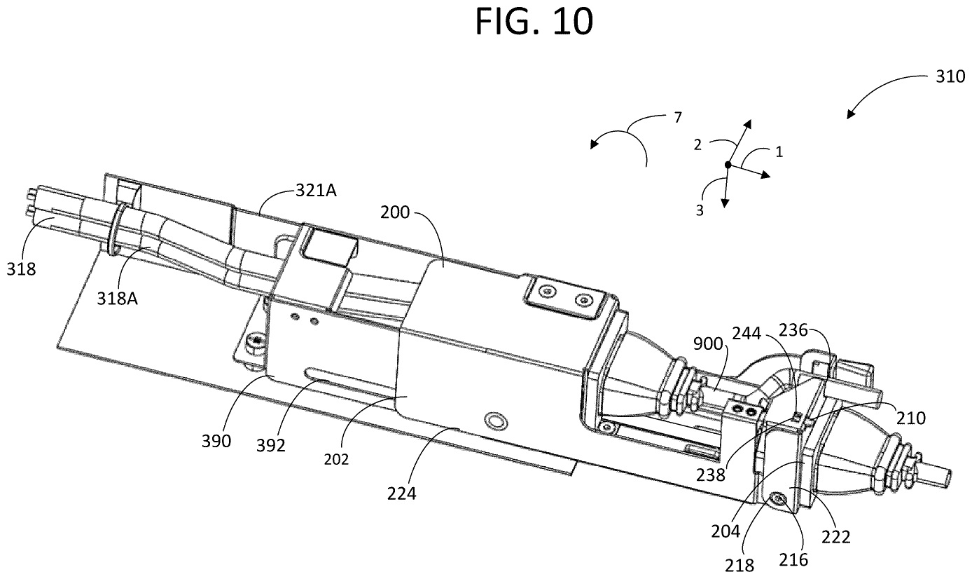

FIG. 10 depicts a perspective view of the information processing device 310 of FIG. 8 having the power input connector module 200 in the extended position and the first power input connector 204 transitioned back to the first orientation from the second orientation. The first support portion 222 of the movable member 202 is rotated along the fourth direction 7 so as to move the first power input connector 204 from the second orientation to the first orientation. In such examples, the pivot pins 216 of the first support portion 222 which are engaged with the recesses 218 of the second support portion 224 may allow the first power input connector 204 to pivot from the second orientation to the first orientation. In such examples, the portion 318A of the first power transfer cable 318 may further move backward along with the first power input connector 204 relative to the second support portion 224 as the first support portion 222 moves from the second orientation towards the first orientation. In some examples, the portion 318A of the first power transfer cable 318 is further tangled to allow the first power input connector 204 to move towards the first orientation. It may be noted that the first orientation may correspond to the position of the first power input connector 204 which is parallel to the axis 1. In some examples, the end of the second external power cord 900 moves inside the power input connector module 200 via the cord opening 236 formed in the first support portion 222 of the movable member 202, when the first power input connector 204 is rotated back to the first orientation. In such examples, as the first power input connector 204 is transitioned back to the first orientation, the second latch 210 automatically secures the first power input connector 204 to the second sidewall of the movable member 202. In particular, the second locking protrusion 244 engages with the second locking groove 238 to secure the first support portion 222 supporting the first power input connector 204 to the second support portion 224 supporting the second power input connector 206.

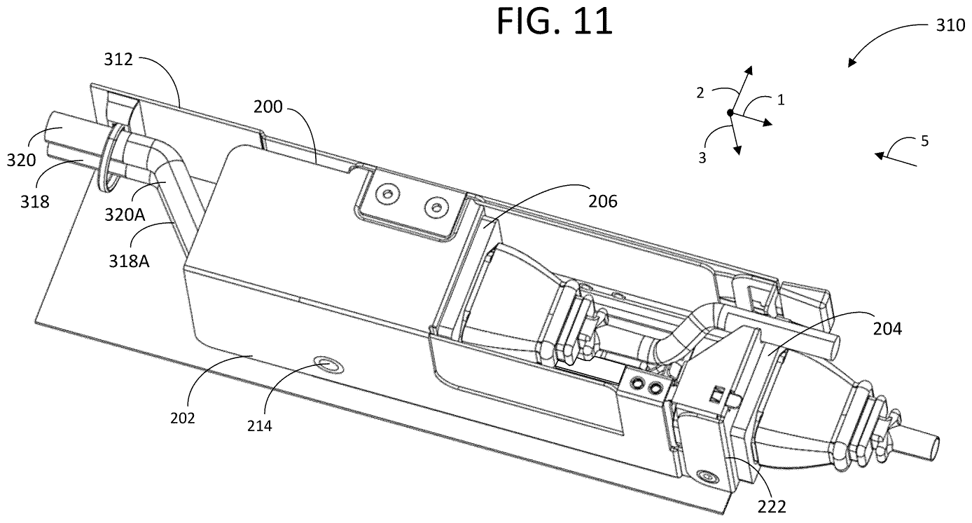

FIG. 11 depicts a perspective view of the information processing device 310 of FIG. 10 having the power input connector module 200 transitioned back to the retracted position from the extended position. In some examples, the first support portion 222 of the movable member 202 is pushed in the second direction 5 along the axis 1 so as to move the movable member 202 from the extended position to the retracted position. In such examples, the pins 214 of the movable member 202 slides along the grooves 392 (as shown in FIG. 10) of the guide member 390 (as shown in FIG. 10) to allow the movable member 202 to move back from the extended position to the retracted position. In such examples, the first and second power input connectors 204, 206 and the portion 318A, 320A of the first and second power transfer cables 318, 320 travel back along with the movable member 202 relative to the chassis 312 as the movable member 202 moves from the extended position to the retracted position. In some examples, the portion 318A, 320A of each of the first and second power transfer cables 318, 320 is tangled to allow the first and second power input connectors 204, 206 to travel backward along with the movable member 202. In such examples, as the power input connector module 200 is transitioned to the retracted position, the first latch 208 automatically secures the power input connector module 200 to the chassis 312. In particular, the first locking protrusions 272 engages with the first locking grooves 344 to secure the movable member 202 to the chassis 312.

FIG. 12A depicts a perspective front view of an information processing device 310. FIG. 12B depicts a perspective rear view of the information processing device 310 of FIG. 12A. In the description hereinafter, FIGS. 12A-12B are described concurrently for ease of illustration. The information processing device 310 may be a computer (e.g., a server, a storage device), a networking device (e.g., a switch, an access point), or the like. In the example of FIGS. 12A-12B, the information processing device 310 is a computer.

The information processing device 310 includes a chassis 312, a first power supply unit 1214, a second power supply unit 1216, a power input connector module 200, a first power transfer cable 318, a second power transfer cable 320, a storage unit 1280, and a plurality of fans 1282.

The first power supply unit 1214 and the second power supply unit 1216 are disposed adjacent to a rear panel 326 of the chassis 312 and both installed in the chassis 312. Similarly, the plurality of fans 1282 is disposed spaced apart from each other along a second axis 2 and are positioned adjacent to the rear panel 326. The power input connector module 200 is disposed adjacent to a front panel 328 of the chassis 312 and one of the peripheral sidewalls 321A of the chassis 312. The storage unit 1280 is disposed adjacent to the power input connector module 200. In some examples, the information processing device 310 may additionally accommodate second and third storage units (not shown). In such examples, the second and third storage units may be disposed spaced apart from each other along the second axis 2 and positioned adjacent to the storage unit 1280. As discussed herein the power input connector module 200 includes a movable member 202, a first power input connector 204, a second power input connector 206, a first latch 208, and a second latch 210. The first power input connector 204 is electrically connected to the first power supply unit 1214 via the first power transfer cable 318. Similarly, the second power input connector 206 is electrically connected to the second power supply unit 1216 via the second power transfer cable 320. The storage unit 1280 and the plurality of fans 1282 are electrically connected to the first and second power supply units 1214, 1216 via suitable transmission circuitry (not shown). In such examples, the power input connector module 200 may facilitate the supply of power from an external power source unit (not shown) via a first external power cord 500 and a second external power cord 900. In particular, the first power input connector 204 is detachably mated with a first power source connector 502 of the first external power cord 500 so as to electrically connect the first power supply unit 1214 with the external power supply unit via the first power transfer cable 318. Similarly, the second power input connector 206 is detachably mated with a second power source connector 902 of the second external power cord 900 so as to electrically connect the second power supply unit 1216 with the external power supply unit via the second power transfer cable 320. In some examples, the second power supply unit 1216 may function as a redundant power supply unit of the information processing device 310. The second power supply unit 316 may be configured to supply power to one or more electronic components of the information processing device 310 in an event of failure (or during maintenance) of the first power supply unit 1214, thereby allowing uninterrupted functioning of the information processing device 310.

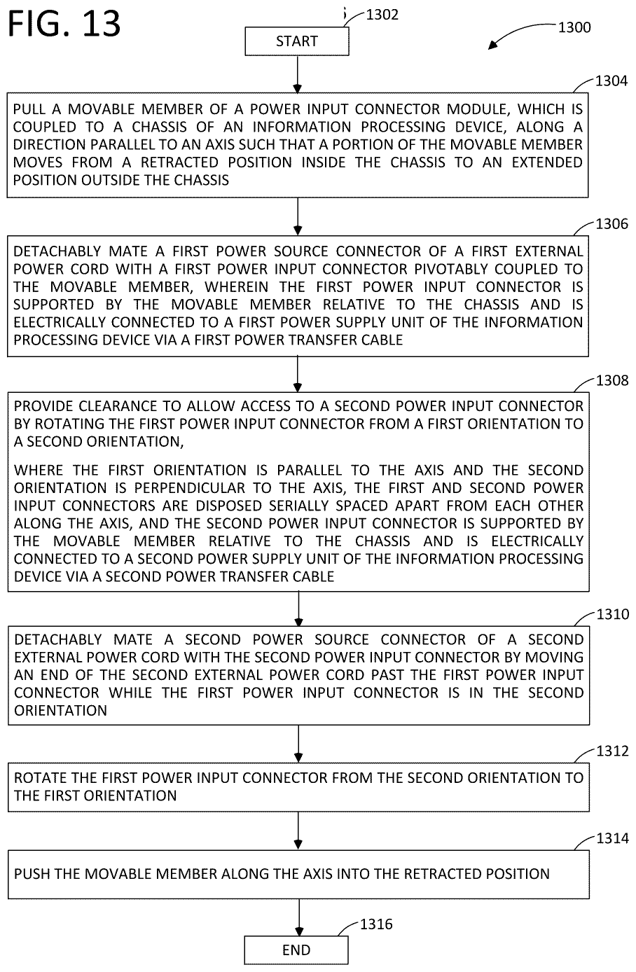

FIG. 13 includes a flowchart showing a method 1300 of connecting a first external power cord and a second external power cord to a first power supply unit and a second power supply unit, respectively, via a power input connector module of an information processing device. It may be noted herein that the method 1300 is described in conjunction with FIGS. 2-11 and 12A-12B, for example. The method 1300 starts at block 1302 and continues to block 1304.

At block 1304, the method 1300 includes pulling a movable member of a power input connector module, which is coupled to a chassis of an information processing device, along a direction parallel to an axis such that a portion of the movable member moves from a retracted position inside the chassis to an extended position outside the chassis. In some examples, in the retracted position of the movable member, the movable member is releasably secured to the chassis by a first latch coupled to the movable member. In such examples, the first latch is actuated to release the movable member from the chassis and later the portion of the movable member is pulled outside the chassis. The method 1300 continues to block 1306.

At block 1306, the method 1300 includes detachably mating a first power source connector of a first external power cord with a first power input connector pivotably coupled to the movable member. The first power input connector is supported by the movable member relative to the chassis and is electrically connected to a first power supply unit of the information processing device via a first power transfer cable. The method 1300 continues to block 1308.

At block 1308, the method 1300 includes providing clearance to allow access to a second power input connector by rotating the first power input connector from a first orientation to a second orientation. In some examples, the first orientation is parallel to the axis and the second orientation is perpendicular to the axis. Further, the first and second power input connectors are disposed serially spaced apart from each other along the axis. The second power input connector is supported by the movable member relative to the chassis and is electrically connected to a second power supply unit of the information processing device via a second power transfer cable. In some examples, in the first orientation of the movable member, the first power input connector is releasably secured to the movable member by a second latch coupled to the movable member. In such examples, the second latch is actuated to release the first power input connector from the movable member and later the first power input connector is rotated from the first orientation to the second orientation. The method 1300 continues to block 1310.

At block 1310, the method 1300 includes detachably mating a second power source connector of a second external power cord with the second power input connector by moving an end of the second external power cord past the first power input connector while the first power input connector is in the second orientation. The method 1300 continues to block 1312.

At block 1312, the method 1300 includes rotating the first power input connector from the second orientation to the first orientation. In such examples, the second latch is re-actuated as the first power input connector reaches the first orientation so as to secure the first power input connector to the movable member. The method 1300 continues to block 1314.

At block 1314, the method 1300 includes pushing the movable member along the axis into the retracted position. In such examples, the first latch is re-actuated as the movable member reaches the retracted position so as to secure the movable member to the chassis. The method 1300 ends at block 1316.

In the foregoing description, numerous details are set forth to provide an understanding of the subject matter disclosed herein. However, implementation may be practiced without some or all of these details. Other implementations may include modifications, combinations, and variations from the details discussed above. It is intended that the following claims cover such modifications and variations.

What is claimed is:

1. A power input connector module comprising:
a movable member configured to be movably connected to a chassis of an information processing device such that the movable member is movable outside the chassis to an extended position and inside the chassis to a retracted position; and
a first power input connector and a second power input connector both disposed serially spaced apart from each other along an axis parallel to a direction of movement of the movable member, and coupled to the chassis via the movable member,
wherein the movable member supports the first and second power input connectors relative to the chassis, and
wherein the first and second power input connectors are configured to travel along with the movable member relative to the chassis as the movable member moves between the extended position and the retracted position.

2. The power input connector module of claim 1, wherein the first power input connector is pivotably coupled to the movable member such that the first power input connector is rotatable relative to the movable member between a first orientation parallel to the axis and a second orientation perpendicular to the axis.

3. The power input connector module of claim 2, wherein, in the first orientation of the first power input connector and in one of the extended position or the retracted position of the movable member, the first power input connector is physically accessible to detachably mate with a first power source connector of a first external power cord.

4. The power input connector module of claim 2, wherein, in the first orientation of the first power input connector and in the retracted position of the movable member, the second power input connector is positioned within the chassis and is not physically accessible to detachably mate with a second power source connector of a second external power cord.

5. The power input connector module of claim 2, wherein, in the second orientation of the first power input connector and in the extended position of the movable member, the second power input connector is physically accessible to detachably mate with a second power source connector of a second external power cord.

6. The power input connector module of claim 2, further comprising a first latch coupled to the movable member, and wherein, in the first orientation of the first power input connector and in the retracted position of the movable member, the first latch is configured to releasably secure the movable member to the chassis.

7. The power input connector module of claim 6, further comprising a second latch coupled to the movable member, and wherein, in the first orientation of the first power input connector, the second latch is configured to releasably secure the first power input connector to the movable member.

8. The power input connector module of claim 1, further comprising a guide member coupled to the chassis, and wherein the movable member is movably connected to the chassis via the guide member.

9. An information processing device comprising:
a chassis;
a first power supply unit and a second power supply unit both installed in the chassis;
a power input connector module disposed in the chassis, comprising:
a movable member movably connected to the chassis such that the movable member is movable outside the chassis to an extended position and inside the chassis to a retracted position; and
a first power input connector and a second power input connector both disposed serially spaced apart from each other along an axis parallel to a direction of movement of the movable member and coupled to the chassis via the movable member, wherein the movable member supports the first and second power input connectors relative to the chassis, wherein the first and second power input connectors are configured to detachably mate with first and second external power cords, respectively;
a first power transfer cable electrically connecting the first power input connector to the first power supply unit; and
a second power transfer cable electrically connecting the second power input connector to the second power supply unit,
wherein the first and second power input connectors and a portion of each of first and second power transfer cables travel along with the movable member relative to the chassis as the movable member moves between the extended position and the retracted position.

10. The information processing device of claim 9, wherein the first power input connector is pivotably coupled to the movable member such that the first power input connector is rotatable relative to the movable member between a first orientation parallel to the axis and a second orientation perpendicular to the axis.

11. The information processing device of claim 10, wherein, in the first orientation of the first power input connector and in one of the extended position or the retracted position of the movable member, the first power input connector is physically accessible to detachably mate with a first power source connector of the first external power cord.

12. The information processing device of claim 10, wherein, in the first orientation of the first power input connector and in the retracted position of the movable member, the second power input connector is positioned within the chassis and is not physically accessible to detachably mate with a second power source connector of the second external power cord.

13. The information processing device of claim 10, wherein, in the second orientation of the first power input connector and in the extended position of the movable member, the second power input connector is physically accessible to detachably mate with a second power source connector of the second external power cord.

14. The information processing device of claim 10, further comprising a first latch coupled to the movable member, and wherein, in the first orientation of the first power input connector and in the retracted position of the movable member, the first latch is configured to releasably secure the movable member to the chassis.

15. The information processing device of claim 10, further comprising a second latch coupled to the movable member, and wherein, in the first orientation of the first power input connector, the second latch is configured to releasably secure the first power input connector to the movable member.

16. The information processing device of claim 9, wherein each of the first and second power input connectors is one of a socket connector or a plug connector, and wherein each of first and second power source connectors of the first and second external power cords, respectively, is another one of the socket connector or the plug connector.

17. The information processing device of claim 9, wherein a first section of the portion of each of the first and second power transfer cables is tied to the movable member and a second section of the portion of each of the first and second power transfer cables is tied to the chassis,
wherein, in the extended position of the movable member, the portion of each of the first and second power transfer cables is untangled to allow the first and second power input connectors to travel forward along with the movable member; and
wherein, in the retracted position of the movable member, the portion of each of the first and second power transfer cables is tangled to allow the first and second power input connectors to travel backward along with the movable member.

18. A method comprising:
pulling a movable member of a power input connector module, which is coupled to a chassis of an information processing device, along a direction parallel to an axis such that a portion of the movable member moves from a retracted position inside the chassis to an extended position outside the chassis;
detachably mating a first power source connector of a first external power cord with a first power input connector pivotably coupled to the movable member, wherein the first power input connector is supported by the movable member relative to the chassis and is electrically connected to a first power supply unit of the information processing device via a first power transfer cable;
providing clearance to allow access to a second power input connector by rotating the first power input connector from a first orientation to a second orientation,
wherein the first orientation is parallel to the axis and the second orientation is perpendicular to the axis, wherein the first and second power input connectors are disposed serially spaced apart from each other along the axis, and wherein the second power input connector is supported by the movable member relative to the chassis and is electrically connected to a second power supply unit of the information processing device via a second power transfer cable;
detachably mating a second power source connector of a second external power cord with the second power input connector by moving an end of the second external power cord past the first power input connector while the first power input connector is in the second orientation;
rotating the first power input connector from the second orientation to the first orientation; and
pushing the movable member along the axis into the retracted position.

19. The method of claim 18, further comprising, in the retracted position of the movable member, releasably securing the movable member to the chassis by using a first latch coupled to the movable member.

20. The method of claim 18, further comprising, in the first orientation of the movable member, releasably securing the first power input connector to the movable member by using a second latch coupled to the movable member.
